(19) United States
(12) Patent Application Publication
(10) Pub. No.: US 2022/0254940 A1
(43) Pub. Date: Aug. 11, 2022

(54) LIGHT-RECEIVING DEVICE AND METHOD OF MANUFACTURING LIGHT-RECEIVING DEVICE

(71) Applicant: Sumitomo Electric Industries, Ltd., Osaka (JP)

(72) Inventors: Takuya OKIMOTO, Osaka-shi (JP); Yoshihiro YONEDA, Osaka-shi (JP)

(73) Assignee: Sumitomo Electric Industries, Ltd., Osaka (JP)

(21) Appl. No.: 17/574,186

(22) Filed: Jan. 12, 2022

(30) Foreign Application Priority Data
Feb. 5, 2021 (JP) 2021-017375

(51) Int. Cl. H01L 31/0232; H01L 31/16; H01L 31/0304; H01L 31/18

(52) U.S. Cl. CPC H01L 31/0232; H01L 31/1844; H01L 31/03046; H01L 31/162

(57) ABSTRACT

A light-receiving device includes a first semiconductor layer having a first conductivity type, an optical waveguide structure on a first region of the first semiconductor layer, and a photodiode structure on a second region adjacent to the first region of the first semiconductor layer. The optical waveguide structure includes a core layer on the first semiconductor layer, and a cladding layer on the core layer. The photodiode structure includes a light-absorbing layer optically coupled with the core layer, and a second semiconductor layer having a second conductivity type on or above the light-absorbing layer. The light-absorbing layer includes a third semiconductor layer having a p-type, and a fourth semiconductor layer having a n-type or an i-type. The third semiconductor layer is disposed between the fourth semiconductor layer and a p-type layer that is one of the first semiconductor layer and the second semiconductor layer.

### CROSS REFERENCE TO RELATED APPLICATIONS

This application claims priority based on Japanese Patent Application No. 2021-017375, filed on Feb. 5, 2021, and the entire contents of the Japanese patent application are incorporated herein by reference.

### TECHNICAL FIELD

The present disclosure relates to light-receiving devices and methods of manufacturing of light-receiving devices.

### BACKGROUND

Japanese Unexamined Patent Application Publication No. 2019-153671 discloses a light-receiving device, which comprises a first semiconductor layer having an n-type conductivity type, an optical waveguide structure on a first region of the first semiconductor layer, and a photodiode structure on a second region adjacent to the first region. The optical waveguide structure consists of a core layer on the first semiconductor layer and a cladding layer on the core layer. The photodiode structure includes a second semiconductor layer provided on the first semiconductor layer alongside the core layer, a light-absorbing layer provided on the second semiconductor layer and optically coupled to the core layer, and a third semiconductor layer provided on the light-absorbing layer having a p-type conductivity. The second semiconductor layer has an n-type or i-type semiconductor layer with a lower dopant concentration than the first semiconductor layer.

### SUMMARY

A light-receiving device according to an embodiment includes a first semiconductor layer having a first conductivity type, an optical waveguide structure disposed on or above a first region of the first semiconductor layer, and a photodiode structure disposed on or above a second region of the first semiconductor layer adjacent to the first region. The optical waveguide structure includes a core layer disposed on or above the first semiconductor layer, and a cladding layer disposed on the core layer. The photodiode structure includes a light-absorbing layer that is disposed on or above the first semiconductor layer and is optically coupled with the core layer, and a second semiconductor layer that has a second conductivity type and is disposed on or above the light-absorbing layer. The light-absorbing layer includes a third semiconductor layer having a p-type, and a fourth semiconductor layer having a n-type or an i-type having a dopant concentration lower than a dopant concentration of an n-type layer that is one of the first semiconductor layer and the second semiconductor layer. The third semiconductor layer is disposed between the fourth semiconductor layer and a p-type layer that is the other of the first semiconductor layer and the second semiconductor layer.

### BRIEF DESCRIPTION OF THE DRAWINGS

The foregoing and other purposes, aspects and advantages will be better understood from the following detailed description with reference to the drawings.

FIG. 1 shows a plan view of a light-receiving apparatus equipped with a light-receiving device according to an embodiment.

FIG. 2 shows a cross section along the line II-II shown in FIG. 1.

FIG. 3 shows an enlarged view of a portion of FIG. 2.

FIG. 4 shows a partial cross-section along the line IV-IV shown in FIG. 1.

FIG. 5 shows a cross-sectional view of a part of a light-receiving device according to a modification.

FIG. 6 shows an energy band diagram of a photodiode structure in a light-receiving device according to a modification.

FIG. 7A shows a cross-sectional view of a step in a method of manufacturing of a light-receiving device.

FIG. 7B shows a cross-sectional view of a step in a method of manufacturing of a light-receiving device.

FIG. 7C shows a cross-sectional view of a step in a method of manufacturing of a light-receiving device.

FIG. 8 shows an example of a frequency response characteristic of a light-receiving device.

FIG. 9 shows an example of a relationship between a distance between a center position of a core layer and an interface and a 3-dB bandwidth.

### DETAILED DESCRIPTION

In the light-receiving device of Japanese Unexamined Patent Application Publication No. 2019-153671, a hole as a minority carrier is generated in the light-absorbing layer due to light absorption. The thinner the light-absorbing layer, the shorter a travelling distance (travelling time) until the hole reaches the p-type semiconductor layer, and the wider a bandwidth of the light-receiving device in terms of a high-frequency response characteristics. However, if the light-absorbing layer is made thinner, an optically coupling efficiency between the core layer and the light-absorbing layer becomes lower, and an optical sensitivity (hereinafter referred to as a sensitivity) of the light-receiving device becomes lower. On the other hand, if the light-absorbing layer is made thicker, the sensitivity of the light-receiving device is improved, but the bandwidth of the light-receiving device becomes narrower. Therefore, there is a trade-off between bandwidth and sensitivity.

The present disclosure provides a light-receiving device capable of operating at a broad bandwidth and a high sensitivity, and a method of manufacturing the light-receiving device.

### [Description of Embodiments of the Present Disclosure]

A light-receiving device according to an embodiment includes a first semiconductor layer having a first conductivity type, an optical waveguide structure disposed on or above a first region of the first semiconductor layer, and a photodiode structure disposed on or above a second region of the first semiconductor layer adjacent to the first region. The optical waveguide structure includes a core layer disposed on or above the first semiconductor layer, and a cladding layer disposed on the core layer. The photodiode structure includes a light-absorbing layer that is disposed on or above the first semiconductor layer and is optically coupled with the core layer, and a second semiconductor layer that has a second conductivity type and is disposed on or above the light-absorbing layer. The light-absorbing layer includes a third semiconductor layer having a p-type, and a fourth semiconductor layer having a n-type or an i-type having a dopant concentration lower than a dopant concentration of an n-type layer that is one of the first semiconductor layer and the second semiconductor layer. The third semiconductor layer is disposed between the fourth semiconductor layer and a p-type layer that is the other of the first semiconductor layer and the second semiconductor layer.

According to the above light-receiving device, the distance between a position where a hole is generated in the fourth semiconductor layer by light absorption and the third semiconductor layer is a travelling distance of the hole. Thus, the travelling distance (travelling time) of the hole can be shortened compared to the case where the light-absorbing layer does not contain the third semiconductor layer. Therefore, the bandwidth of the light-receiving device can be widened while the light-absorbing layer is thickened to improve the sensitivity of the light-receiving device. Consequently, the above light-receiving device can be operated with a broad bandwidth and a high sensitivity.

An interface between the third semiconductor layer and the fourth semiconductor layer may be a homojunction surface. In this case, there is no discontinuity in energy level at the interface between the third semiconductor layer and the fourth semiconductor layer.

In a thickness direction of the first semiconductor layer, a distance between a center position of the core layer and an interface between the third semiconductor layer and the fourth semiconductor layer may be less than or equal to 100 nm. In this case, a density of holes generated in the fourth semiconductor layer is higher at a position adjacent to a center position of the core layer where the light intensity is maximum. Due to the small distance between the center position of the core layer and the interface, the distance that many of the holes travel to the interface can be shortened.

A p-type dopant concentration at an interface between the third semiconductor layer and the fourth semiconductor layer may be greater than or equal to 5×10¹⁵ cm⁻³ and less than or equal to 5×10¹⁷ cm⁻³.

A method of manufacturing light-receiving device according to an embodiment includes forming a first semiconductor layer having a first conductivity type on a substrate, forming a light-absorbing layer on or above the first semiconductor layer, forming a second semiconductor layer having a second conductivity type on or above the light-absorbing layer, etching away the light-absorbing layer and the second semiconductor layer on or above a first region of the first semiconductor layer to form a photodiode structure including the light-absorbing layer and the second semiconductor layer on or above a second region of the first semiconductor layer adjacent to the first region, and forming an optical waveguide structure on or above the first region of the first semiconductor layer, the optical waveguide structure including a core layer optically coupled with the light-absorbing layer and a cladding layer disposed on the core layer. The light-absorbing layer includes a third semiconductor layer having a p-type, and a fourth semiconductor layer having a n-type or an i-type having a dopant concentration lower than a dopant concentration of an n-type layer that is one of the first semiconductor layer and the second semiconductor layer. The third semiconductor layer is disposed between the fourth semiconductor layer and a p-type layer that is the other of the first semiconductor layer and the second semiconductor layer.

In the light-receiving device obtained by the above method of manufacturing, the distance between a position where a hole is generated in the fourth semiconductor layer by a light absorption and the third semiconductor layer is a travelling distance of the hole. Therefore, the travelling distance (travelling time) of the hole can be shortened compared to the case where the light-absorbing layer does not contain the third semiconductor layer. Therefore, a bandwidth of the light-receiving device can be increased while a sensitivity of the light-receiving device is improved by thickening the light-absorbing layer. Therefore, according to the above method of manufacturing, the light-receiving device that can operate with a broad bandwidth and a high sensitivity can be obtained.

Before forming the optical waveguide structure, in a thickness direction of the first semiconductor layer, an interface between the third semiconductor layer and the fourth semiconductor layer may be farther than a position corresponding to a center position of the core layer from the n-type layer that is one of the first semiconductor layer and the second semiconductor layer. In this case, when the core layer and the cladding layer are formed, the p-type dopant in the third semiconductor layer diffuses toward the fourth semiconductor layer due to heating. Therefore, in the thickness direction of the first semiconductor layer, the interface between the third semiconductor layer and the fourth semiconductor layer moves closer to the n-type layer. As a result, in the thickness direction of the first semiconductor layer, the difference between the center position of the core layer and the interface between the third semiconductor layer and the fourth semiconductor layer becomes smaller.

### Details of Embodiments of the Present Disclosure

Embodiments of the present disclosure will be described in detail with reference to the accompanying drawings. In the description of the drawings, the same reference numerals are used for the same or equivalent elements, and redundant explanations are omitted. In the following description, “undoped” means an extremely low dopant concentration (impurity concentration) of, for example, 1×10¹⁵ cm⁻³ or less. In the drawings, a first direction A, a second direction B, and a third direction C are illustrated. First direction A, second direction B, and third direction C intersect each other (e.g., orthogonally).

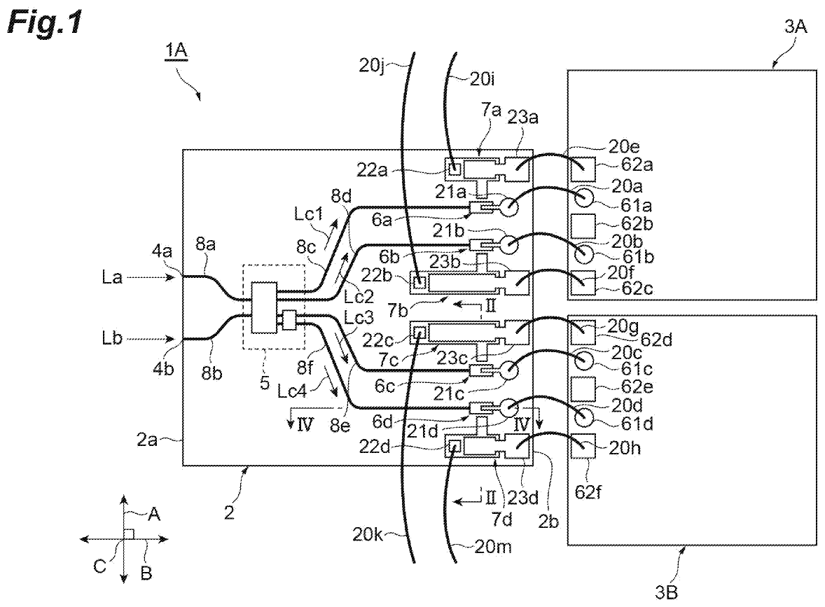

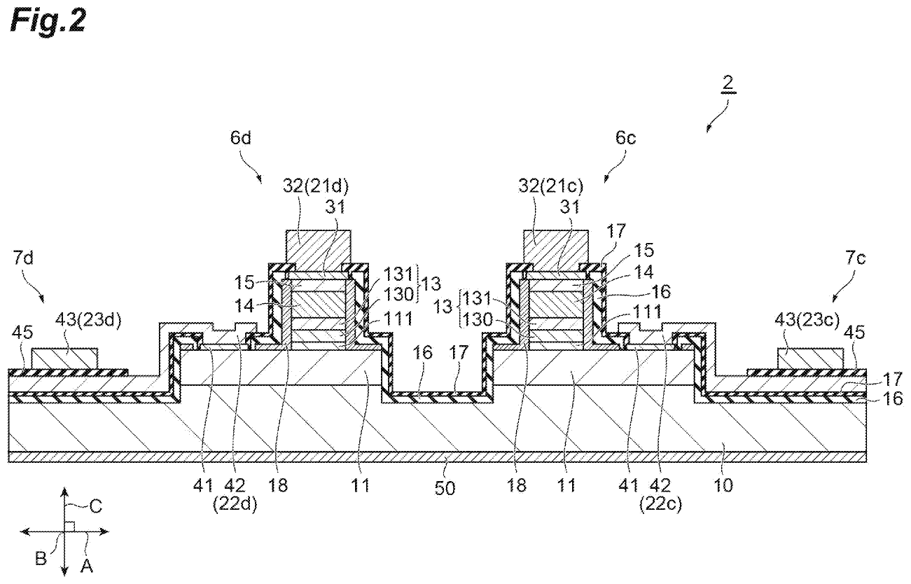

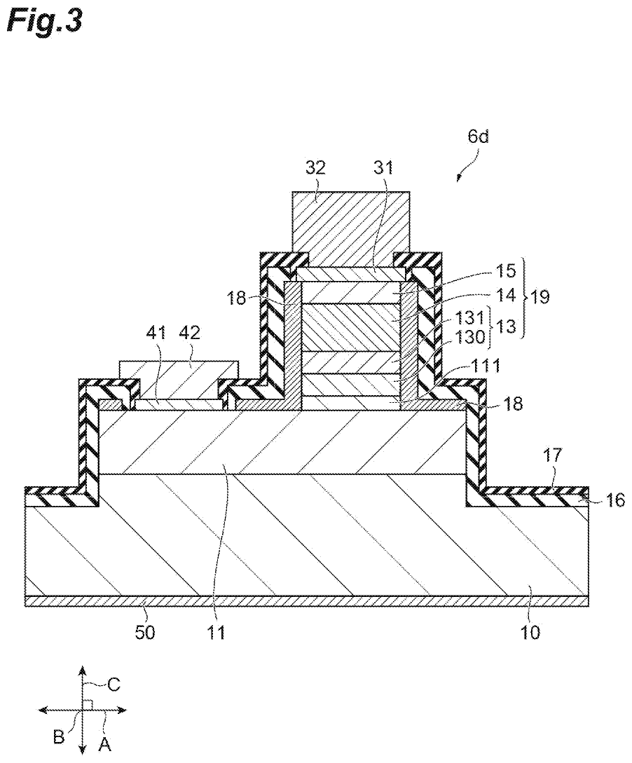

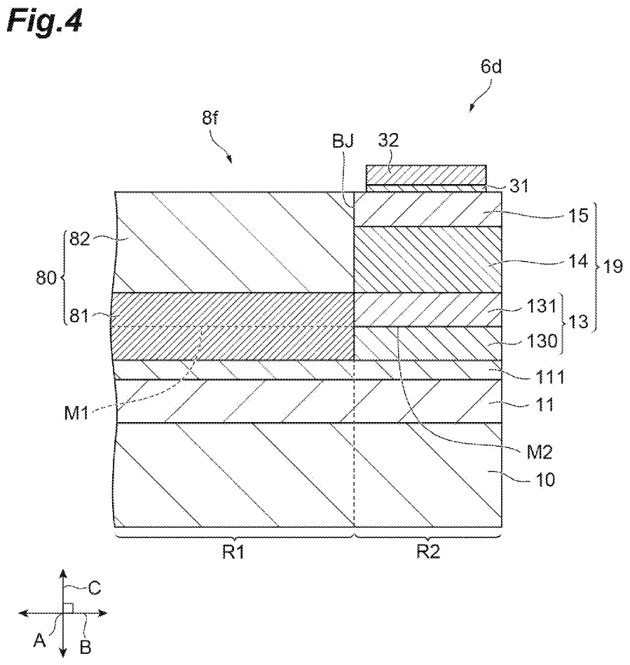

FIG. 1 shows a plan view of a light-receiving apparatus equipped with a light-receiving device according to an embodiment. FIG. 2 shows a cross-section along the line II-II shown in FIG. 1. FIG. 3 shows an enlarged view of a portion of FIG. 2. FIG. 4 shows a partial cross-section along the line IV-IV shown in FIG. 1. Alight-receiving apparatus 1A shown in FIG. 1 can be mainly used for coherent light communication systems.

Light-receiving apparatus 1A has a light-receiving device 2 and signal-amplifying portions 3A, 3B. Light-receiving device 2 may have a planar shape, such as a rectangular shape. Light-receiving device 2 may include an optical waveguide formed on a substrate 10 (see FIG. 2). Light-receiving device 2 has two input ports 4a, 4b and an optical branching portion 5 (light coupler). Light-receiving device 2 may further include light-receiving element portions 6a to 6d and capacitive element portions 7a, 7b, 7c, 7d. Input ports 4a and 4b, optical branching portion 5 (light coupler), light-receiving element portions 6a to 6d, capacitive element portions 7a to 7d, and the optical waveguide can be monolithically integrated on substrate 10 as a common substrate.

Light-receiving device 2 may have a first edge 2a and a second edge 2b extending along first direction A. First edge 2a and second edge 2b are located on opposite sides of each other in second direction B. First direction A and second direction B are directions along a principal surface of substrate 10. Two input ports 4a, 4b are provided on first edge 2a of light-receiving device 2. An optical signal La is input to one of the two input ports 4a and 4b from the outside of light-receiving apparatus 1A. Optical signal La contains four signal components modulated by the QPSK (Quadrature Phase Shift Keying) method. A local oscillator light Lb is input to the other input port 4b. Input ports 4a and 4b are optically coupled to optical branching portion 5 via optical waveguide portions 8a and 8b, respectively. Optical waveguide portions 8a and 8b each have a core layer and a cladding layer covering the core layer. The core layer contains a material with a relatively large refractive index (e.g. InGaAsP). The cladding layer contains a material with a refractive index smaller than that of the core layer (e.g. InP)

Optical branching portion 5 may include a MMI (Multi-Mode Interference) coupler and a 90° optical hybrid. Optical branching portion 5 branches optical signal La into four signal components Lc1, Lc2, Lc3, and Lc4 by making interference of optical signal La and local oscillator light Lb with each other. Polarization states of signal components Lc1 and Lc2 are equal to each other. Signal components Lc1 and Lc2 have an In-phase relationship. Polarization states of signal components Lc3 and Lc4 are equal to each other and different from the polarization states of signal components Lc1 and Lc2. Signal components Lc3 and Lc4 have a Quadrature relationship.

Each of light-receiving element portions 6a to 6d may include a PIN photodiode. Light-receiving element portions 6a to 6d are arranged in sequence along second edge 2b of light-receiving device 2. Light-receiving element portions 6a to 6d are optically coupled to the four output ends of optical branching portion 5 via optical waveguide portions 8c to 8f. Each cathode of light-receiving element portions 6a to 6d is supplied with a bias voltage. Light-receiving element portions 6a to 6d receive four signal components Lc1 to Lc4 from optical branching portion 5, respectively. Light-receiving element portions 6a to 6d generate electrical signals (light currents) according to light intensities of signal components Lc1 to Lc4, respectively. Each anode of light-receiving element portions 6a to 6d is electrically connected to each of signal-output electrode pads 21a, 21b, 21c, and 21d, respectively. Signal-output electrode pads 21a to 21d are mounted on light-receiving device 2. Signal-output electrode pads 21a to 21d are provided along second edge 2b of light-receiving device 2, in line with first direction A. Signal-output electrode pads 21a through 21d are electrically connected to signal-input electrode pads 61a through 61d of signal-amplifying portions 3A and 3B via bonding wires 20a, 20b, 20c, and 20d, respectively.

FIG. 2 shows a cross-sectional structure of two light-receiving element portions 6c and 6d out of the four light-receiving element portions 6a to 6d. FIG. 3 shows a cross-sectional structure of light-receiving element portion 6d. The cross-sectional structures of other light-receiving element portions 6a and 6b are similar to those of light-receiving element portions 6c and 6d. Each of capacitive element portions 7a to 7d may include a lower metal layer, an upper metal layer, and an insulating film 45. Insulating film 45 is sandwiched between the lower metal layer and upper metal layer. The lower metal layer, the upper metal layer, and insulation film 45 constitute the so-called MIM (Metal-Insulator-Metal) capacitor. Each of the lower metal layer and upper metal layer has a multilayer structure such as TiW/Au or Ti/Pt/Au. Capacitive element portions 7a through 7d are located along second edge 2b on light-receiving device 2. Each of capacitive element portions 7a to 7d is arranged adjacently (side by side) to each of light-receiving element portions 6a to 6d. Each of capacitive element portions 7a to 7d is electrically connected between a bias conductor line 42 and a reference potential conductor line (GND line). Bias conductor line 42 provides a bias voltage to each cathode of light-receiving element portions 6a to 6d. Bias conductor line 42 is used as the lower metal layer of capacitive element portions 7a to 7d. Upper metal layers 43 of capacitive element portions 7a to 7d extend toward electrode pads 23a, 23b, 23c, and 23d each having a reference potential, or form a part of electrode pads 23a to 23d. Electrode pads 23a to 23d are located along second edge 2b of light-receiving device 2. Electrode pads 23a to 23d are electrically connected to a metal film 50 disposed on a backside of substrate 10 via through holes (not shown) that penetrate substrate 10. Each lower metal layer (bias conductor line 42) of capacitive element portions 7a to 7d extends along the principal surface of substrate 10. Capacitive element portions 7a to 7d allow the inductance components between the cathodes of element portions 6a to 6d and the bypass capacitor (not shown) to be aligned by design.

Capacitive element portions 7a through 7d have electrode pads 22a, 22b, 22c, and 22d, respectively, connected to the lower metal layer (bias conductor line 42). The bias voltage is applied to electrode pads 22a to 22d. Electrode pads 23a to 23d are placed between electrode pads 22a to 22d and second edge 2b of light-receiving device 2 in second direction B.

First ends of bonding wires 20i, 20j, 20k, and 20m are connected to electrode pads 22a to 22d, respectively. Second ends of bonding wires 20i to 20m are electrically connected to a bias voltage source not shown in the figure. Bonding wires 20i to 20m form part of conductor lines that supply the bias voltages to light-receiving element portions 6a to 6d, respectively.

First ends of bonding wires 20e, 20f, 20g, and 20h are connected to electrode pads 23a to 23d. Bonding wires 20e to 20h are provided along the extending direction of bonding wires 20a to 20d. The other ends of bonding wires 20e to 20h are connected to reference-potential electrode pads 62a, 62c, 62d and 62f of signal-amplifying portions 3A and 3B, respectively.

In the embodiment, capacitive element portions 7a to 7d and light-receiving element portions 6a to 6d are monolithically integrated on substrate 10. Capacitive element portions 7a to 7d are located near light-receiving element portions 6a to 6d, respectively. In addition, each one electrode (upper metal layer 43) of capacitive element portions 7a to 7d is grounded to metal film 50 via the through hole penetrating substrate 10. The one electrode (upper metal layer 43) of each of capacitive element portions 7a to 7d is connected to the reference potential of signal-amplifying portions 3A and 3B via metal film 50. Thus, the quality of the reference potential of light-receiving element portions 6a to 6d can be increased.

Signal-amplifying portions 3A and 3B have TIAs (Trans Impedance Amplifiers) that amplify the electrical signals (light currents) output from light-receiving element portions 6a to 6d. Signal-amplifying portion 3A and 3B are located behind light-receiving device 2. Signal-amplifying portion 3A has two signal-input electrode pads 61a and 61b. Signal-amplifying portion 3A generates a voltage signal by differential amplification of the electrical signals input to signal-input electrode pads 61a and 61b. Signal-amplifying portion 3B has two signal-input electrode pads 61c and 61d. Signal-amplifying portion 3B generates a voltage signal by differential amplification of the electrical signals input to signal-input electrode pads 61c and 61d. Signal-input electrode pads 61a to 61d are arranged in order along second edge 2b of light-receiving device 2 in first direction A. As described above, signal-input electrode pads 61a to 61d are electrically connected to signal-output electrode pads 21a to 21d via bonding wires 20a to 20d, respectively.

Signal-amplifying portion 3A further includes three reference-potential electrode pads 62a, 62b, and 62c. Reference-potential electrode pads 62a to 62c are arranged along second edge 2b of light-receiving device 2 in first direction A. Signal-input electrode pad 61a is located between reference-potential electrode pads 62a and 62b. Signal-input electrode pad 61b is located between reference-potential electrode pads 62b and 62c. Similarly, signal-amplifying portion 3B further includes three reference-potential electrode pads 62d, 62e, and 62f. Reference-potential electrode pads 62d to 62f are arranged in order along second edge 2b of light-receiving device 2, along first direction A. Signal-input electrode pad 61c described above is placed between reference-potential electrode pads 62d and 62e. Signal-input electrode pad 61d is placed between reference-potential electrode pads 62e and 62f. As mentioned above, reference-potential electrode pads 62a, 62c, 62d and 62f of signal-amplifying portions 3A and 3B are electrically connected to electrode pads 23a to 23d via bonding wires 20e to 20h, respectively.

FIG. 4 shows a cross-sectional structure of a junction between light-receiving element portion 6d and optical waveguide portion 8f FIG. 4 shows the cross section along second direction B which is a light propagating direction of optical waveguide portion 8f Other junctions (a junction between light-receiving element portion 6a and optical waveguide portion 8c, a junction between light-receiving element portion 6b and optical waveguide portion 8d, and a junction of light-receiving element portion 6c and optical waveguide 8e) have similar cross-sectional structures as the junction between light-receiving element portion 6d and optical waveguide portion 8f Light-receiving element portions 6a to 6d and optical waveguide portions 8c to 8f are integrated on substrate 10 as the common substrate.

Optical waveguide portion 8f has a first semiconductor layer 11 having a first conductivity type and an optical waveguide structure 80 provided on a first region R1 of first semiconductor layer 11. The first conductivity type is, for example, n-type. First semiconductor layer 11 is provided on substrate 10. Optical waveguide structure 80 has a core layer 81 provided on first semiconductor layer 11 and a cladding layer 82 provided on core layer 81. A buffer layer 111 may be provided between first semiconductor layer 11 and core layer 81. Buffer layer 111 has the first conductivity type.

Light-receiving element portion 6d has first semiconductor layer 11 and a photodiode structure 19 provided on a second region R2 of first semiconductor layer 11. Second region R2 is adjacent to first region R1. Photodiode structure 19 includes a light-absorbing layer 13 provided on first semiconductor layer 11, and includes a second semiconductor layer 14 provided on light-absorbing layer 13. Second semiconductor layer 14 has a second conductivity type. The second conductivity type is the opposite conductivity type to the first conductivity type, for example, a p-type. Buffer layer 111 may be provided between first semiconductor layer 11 and light-absorbing layer 13. Photodiode structure 19 may have a contact layer 15 having the second conductivity type provided on second semiconductor layer 14.

Optical waveguide portion 8f and light-receiving element portion 6d are joined by a butt-joint interface BJ. In butt-joint interface BJ, core layer 81 and light-absorbing layer 13 are in contact with each other. In butt-joint interface BJ, cladding layer 82 and second semiconductor layer 14 are in contact with each other, and cladding layer 82 and contact layer 15 are in contact with each other.

Substrate 10 may be a semi-insulating III-V compound semiconductor substrate. Substrate 10 is, for example, a semi-insulating InP substrate.

First semiconductor layer 11 and buffer layer 111 are semiconductor layers common to optical waveguide portion 8f and light-receiving element portion 6d, and function as a lower cladding layer in optical waveguide portion 8f Each of first semiconductor layer 11 and buffer layer 111 is a III-V compound semiconductor layer, such as an n-type InP layer. Examples of n-type dopants include Si. The n-type dopant concentration of first semiconductor layer 11 is, for example, 1×10¹⁷ cm⁻³ or higher. Buffer layer 111 has a lower dopant concentration than that of first semiconductor layer 11. A thickness of first semiconductor layer 11 is, for example, from 1 μm to 2 μm.

Core layer 81 has a reflective index that is larger than reflective indices of first semiconductor layer 11 and buffer layer 111. Core layer 81 contains a semiconductor material (e.g., InGaAsP) that is lattice-matched to buffer layer 111. A bandgap wavelength of core layer 81 is 1.05 for example. A thickness of core layer 81 is, for example, 0.3 μm to 0.5 μm.

Cladding layer 82 has a refractive index that is smaller than the refractive index of core layer 81. Cladding layer 82 contains a semiconductor material (e.g. InP) that is lattice-matched to core layer 81. A thickness of cladding layer 82 is, for example, 1 μm to 3 μm.

Light-absorbing layer 13 is optically coupled to core layer 81. Light-absorbing layer 13 may have a thickness less than or equal to the thickness of core layer 81. Light-absorbing layer 13 has a third semiconductor layer 131 and a fourth semiconductor layer 130. Third semiconductor layer 131 is disposed between fourth semiconductor layer 130 and the p-type layer that is one of first semiconductor layer 11 and second semiconductor layer 14. In this embodiment, since first semiconductor layer 11 is the n-type layer and second semiconductor layer 14 is the p-type layer, third semiconductor layer 131 is placed between fourth semiconductor layer 130 and second semiconductor layer 14.

Third semiconductor layer 131 has the p-type conductivity. Examples of p-type dopants include Zn. Third semiconductor layer 131 is a III-V compound semiconductor layer, such as a GalnAs layer. Third semiconductor layer 131 has a bandgap that is smaller than a bandgap of second semiconductor layer 14. The p-type dopant concentration of third semiconductor layer 131 is lower than the dopant concentration of second semiconductor layer 14. The p-type dopant concentration of third semiconductor layer 131 may monotonically decrease toward fourth semiconductor layer 130. Third semiconductor layer 131 may have a p-type dopant concentration greater than or equal to 5×10¹⁶ cm⁻³ and less than or equal to 1×10¹⁸cm⁻³, for example. A thickness of third semiconductor layer 131 is, for example, from 0.1 μm to 0.4 μm.

Fourth semiconductor layer 130 is an n-type or i-type semiconductor layer having a lower dopant concentration than the n-type layer that is one of first semiconductor layer 11 and second semiconductor layer 14. Fourth semiconductor layer 130 is a III-V compound semiconductor layer, such as a GainAs layer. A bandgap of fourth semiconductor layer 130 is smaller than that of second semiconductor layer 14. Fourth semiconductor layer 130 has an n-type dopant concentration that is lower than the n-type dopant concentration of first semiconductor layer 11 and lower than the n-type dopant concentration of buffer layer 111. Fourth semiconductor layer 130 may be undoped. The n-type dopant concentration of fourth semiconductor layer 130 may be greater than or equal to 5×10¹⁵ cm⁻³ and less than or equal to 1×10¹⁷ cm⁻³. A thickness of fourth semiconductor layer 130 may be greater than or equal to the thickness of third semiconductor layer 131, for example, 0.1 μm to 0.4 μm.

An interface M2 between third semiconductor layer 131 and fourth semiconductor layer 130 may be a homojunction surface. In this case, fourth semiconductor layer 130 contains the same III-V compound semiconductor material as third semiconductor layer 131. Fourth semiconductor layer 130 may include a III-V compound semiconductor material different from third semiconductor layer 131.

A thickness direction of first semiconductor layer 11 is the same as third direction C, which intersects the principal surface of substrate 10. In third direction C, core layer 81 has a center position M1. A distance from a top surface of core layer 81 to center position M1 is the same as a distance from a bottom surface of core layer 81 to center position M1. In third direction C, interface M2 may be located at a center of light-absorbing layer 13. A difference from center position M1 to interface M2 along third direction C is less than or equal to 100 nm. More specifically, a distance between center position M1 and interface M2 at butt-joint interface BJ in third direction C 100 nm or less. The distance between center position M1 and interface M2 in third direction C may be less than 100 nm, 50 nm or less, or 0 nm. The p-type dopant concentration at interface M2 may be 5×10¹⁵ cm⁻³ or greater and 5×10¹⁷ cm⁻³ or less.

Second semiconductor layer 14 is a III-V compound semiconductor layer, such as a p-type InP layer. The p-type dopant concentration of second semiconductor layer 14 is 5×10¹⁷ cm⁻³ or greater, for example. A thickness of second semiconductor layer 14 is, for example, 0.5 μm to 3 μm.

A contact layer 15 is a GalnAs layer including a p-type dopant, for example. The p-type dopant concentration of contact layer 15 is 1×10¹⁸ cm⁻³ or greater, for example. Contact layer 15 has a dopant concentration higher than a dopant concentration of second semiconductor layer 14. A thickness of contact layer 15 is, for example, 0.1 μm to 0.3 μm.

Between light-absorbing layer 13 and second semiconductor layer 14, InGaAsP layer having the second conductivity type may be provided. The InGaAsP layer may be a composition graded layer. The composition graded layer mitigates the hetero-energy barrier (AEv: energy level difference in the valence electron band) between light-absorbing layer 13 and second semiconductor layer 14. The composition graded layer may include, for example, two layers of undoped or doped InGaAsP. Bandgap wavelengths of the two layers are, for example, 1.3 μm and 1.1 μm, respectively. A dopant concentration of the composition graded layer is, for example, equal to or less than 5×10¹⁷ cm⁻³.

A heterobarrier relaxation layer having the second conductivity type may be provided between second semiconductor layer 14 and contact layer 15. A dopant concentration of the heterobarrier relaxation layer is, for example, 1×10¹⁸ cm⁻³ or higher. The heterobarrier relaxation layer may include, for example, two layers of doped InGaAsP. Bandgap wavelengths of the two layers are, for example, 1.3 μm and 1.1 μm, respectively.

As shown in FIG. 3, light-receiving element portion 6d has a mesa structure extending in second direction B. The mesa structure includes photodiode structure 19 and buffer layer 111. The mesa structure has a pair of side surfaces. The side surfaces are embedded by an embedding region 18 containing a semi-insulating material, such as Fe-doped InP. A width of the mesa structure along first direction A is, for example, 1.5 μm to 3 μm, and a height of the mesa structure along third direction C is, for example, 2 μm to 3.5 μm.

Light-receiving element portion 6d may further include insulation films 16, 17. Insulation films 16, 17 include, for example, insulating silicon compounds (SiN, SiON, or SiO₂). Insulating films 16, 17 are provided so as to cover substrate 10 and embedding region 18. Insulating films 16, 17 have a first opening on the top surface of the mesa structure. An ohmic electrode 31 is disposed in the first opening. Ohmic electrode 31 is connected to contact layer 15 through the first opening. Ohmic electrode 31 includes, for example, an alloy of contact layer 15 and Pt or AuZn. A conductor line 32 is provided on ohmic electrode 31. Conductor line 32 extends in second direction B and electrically connects ohmic electrode 31 to signal-output electrode pad 21d. Signal-output electrode pad 21d includes a layered structure such as TiW/Au or Ti/Pt/Au. Signal-output electrode pad 21d includes, for example, Au.

Insulation films 16, 17 have a second opening on first semiconductor layer 11 away from the mesa structure of light-receiving element portion 6d. An ohmic electrode 41 is provided in the second opening. Ohmic electrode 41 is connected to first semiconductor layer 11 through the second opening. Ohmic electrode 41 includes, for example, AuGe or AuGeNi alloyed with first semiconductor layer 11. On ohmic electrode 41, bias conductor line 42 is provided. As shown in FIG. 2, bias conductor line 42 extends to the lower metal layer of the capacitive element 7d, and electrically connects the lower metal layer to ohmic electrode 41.

Optical waveguide portion 8f has a mesa structure extending in second direction B, similar to light-receiving element portion 6d. A pair of side surfaces and top surface of the mesa structure may be covered by insulation films 16, 17.

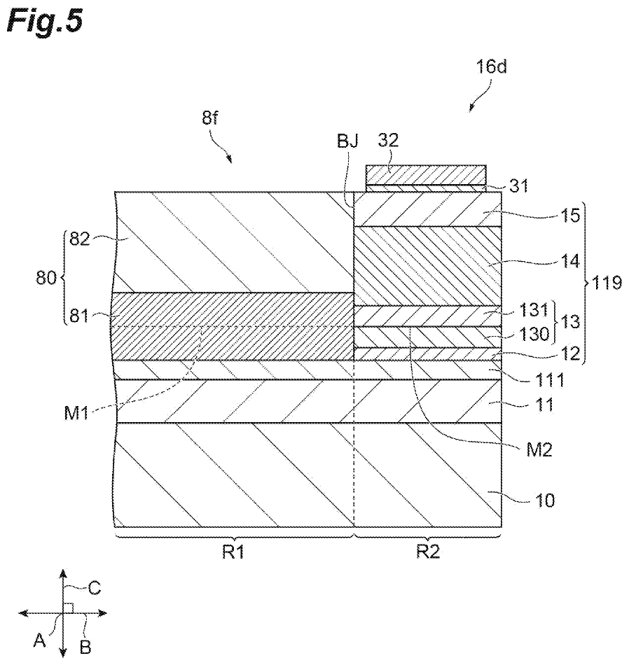

FIG. 5 shows a cross-sectional view of a part of light-receiving device in a modification. A light-receiving device in this modification has a light-receiving element portion 16d instead of light-receiving element portion 6d. Each of light-receiving element portions 6a to 6c is also replaced with light-receiving element portion 16d. Light-receiving element portion 16d is equipped with a photodiode structure 119 instead of photodiode structure 19. Photodiode structure 119 has the same structure as photodiode structure 19, except that photodiode structure 119 is further equipped with a semiconductor layer 12 (fifth semiconductor layer). Semiconductor layer 12 is placed between buffer layer 111 and fourth semiconductor layer 130. Core layer 81 and semiconductor layer 12 are contact with each other at butt-joint interface BJ. In photodiode structure 119, a thickness of second semiconductor layer 14 is larger than that of second semiconductor layer 14 in photodiode structure 19. As a result, core layer 81 and second semiconductor layer 14 are in contact with each other in butt-joint interface BJ.

Semiconductor layer 12 has a bandgap that is larger than the bandgap of fourth semiconductor layer 130 and smaller than the bandgaps of first semiconductor layer 11 and buffer layer 111. Semiconductor layer 12 is a III-V compound semiconductor layer, such as a GaInAsP layer. Semiconductor layer 12 has an n-type dopant concentration that is lower than the n-type dopant concentration of first semiconductor layer 11 and lower than the n-type dopant concentration of buffer layer 111. Semiconductor layer 12 may be an undoped layer. The n-type dopant concentration of semiconductor layer 12 is 1×10¹⁶ cm⁻³ or less, for example. A thickness of semiconductor layer 12 is, for example, 0.1 μm to 0.2 μm.

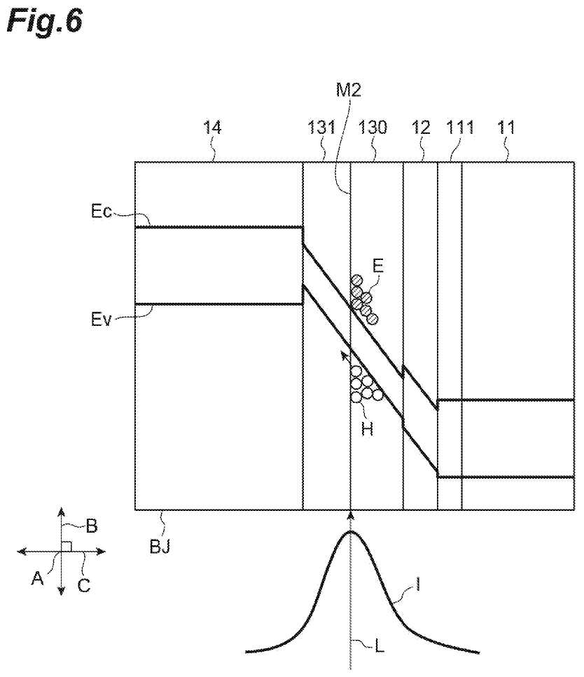

FIG. 6 shows an energy band diagram of the photodiode structure in the light-receiving device of the modification. In FIG. 6, an energy level Ec of conduction band in photodiode structure 119 and an energy level Ev of valence band in photodiode structure 119 are illustrated. When a light L from core layer 81 passes through butt-joint interface BJ and enters light-absorbing layer 13, holes H and electrons E are generated in fourth semiconductor layer 130. Holes H are minority carriers in fourth semiconductor layer 130. Holes H generated in fourth semiconductor layer 130 travel to interface M2 in a direction from fourth semiconductor layer 130 toward third semiconductor layer 131. A distance from a position where hole H is generated to interface M2 is the traveling distance of the hole. Therefore, in case light-absorbing layer 13 includes third semiconductor layer 131, the traveling distance (traveling time) of hole H is smaller than in case light-absorbing layer 13 does not include third semiconductor layer 131. In light-receiving device 2 which is not provided with semiconductor layer 12 shown in FIG. 1 to FIG. 4, the travelling distance of hole H can be shortened similarly. Therefore, the bandwidth of light-receiving device 2 can be widened while the sensitivity of light-receiving device 2 can be improved by thickening light-absorbing layer 13. Consequently, light-receiving device 2 can be operated with a broad bandwidth and a high sensitivity. Similarly, the light-receiving device in the modification can also be operated with a broad bandwidth and a high sensitivity.

When interface M2 between third semiconductor layer 131 and fourth semiconductor layer 130 is a homojunction surface, there is no discontinuity in energy level Ev of the valence band at interface M2. As a result, pile-up of holes H can be suppressed.

In third direction C, when the distance between center position M1 and interface M2 of core layer 81 is 100 nm or less, a density of holes H generated in fourth semiconductor layer 130 becomes high at a position adjacent to center position M1 of core layer 81 where the intensity of light L having an intensity distribution I is maximum. If the distance along butt-joint interface BJ between center position M1 of core layer 81 and interface M2 is small, the traveling distances of many holes H can be shortened.

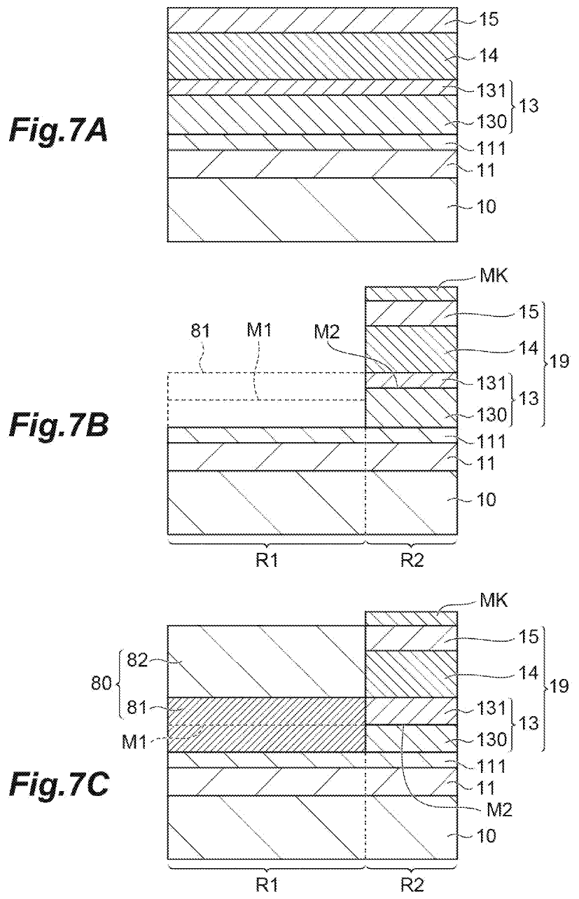

FIG. 7A to FIG. 7C show cross-sectional views of steps in a method of manufacturing of a light-receiving device. Light-receiving device 2 shown in FIG. 1 may be manufactured as follows.

(formation of first semiconductor layer) First, as shown in FIG. 7A, first semiconductor layer 11 having a first conductivity type is formed on substrate 10. Then, buffer layer 111 may be formed on first semiconductor layer 11.

(formation of light-absorbing layer) Next, as shown in FIG. 7A, light-absorbing layer 13 is formed on first semiconductor layer 11. In this embodiment, after forming fourth semiconductor layer 130 on first semiconductor layer 11, third semiconductor layer 131 is formed on fourth semiconductor layer 130. The thickness of fourth semiconductor layer 130 is larger than the thickness of third semiconductor layer 131.

(Formation of Second Semiconductor Layer)

Next, as shown in FIG. 7A, second semiconductor layer 14 having a second conductivity type is formed on light-absorbing layer 13. Then, contact layer 15 may be formed on second semiconductor layer. First semiconductor layer 11, buffer layer 111, fourth semiconductor layer 130, third semiconductor layer 131, second semiconductor layer 14 and contact layer 15 are formed by, for example, organometallic vapor phase epitaxy method or molecular beam epitaxy method.

(Formation of Photodiode Structure)

Next, as shown in FIG. 7B, light-absorbing layer 13, second semiconductor layer 14, and contact layer 15 on first region R1 of first semiconductor layer 11 are removed by etching. Then, photodiode structure 19 is formed on second region R2 adjacent to first region R1 of first semiconductor layer 11. Etching is performed on second region R2 of first semiconductor layer 11 using a mask MK provided on contact layer 15. Etching is done by wet etching, for example.

In the thickness direction of first semiconductor layer 11, interface M2 between third semiconductor layer 131 and fourth semiconductor layer 130 is farther than the position corresponding to center position M1 of core layer 81 from first semiconductor layer 11.

(Formation of Optical Waveguide Structure)

Next, as shown in FIG. 7C, optical waveguide structure 80 is formed on first region R1 of first semiconductor layer 11. In this embodiment, core layer 81 is formed on first region R1 of first semiconductor layer 11, and then cladding layer 82 is formed on core layer 81. Core layer 81 and cladding layer 82 are formed by a butt-joint growth of organometallic vapor phase epitaxy method or molecular beam epitaxy method. The butt-joint growth of core layer 81 and cladding layer 82 is performed using mask MK. After removing mask MK, embedding region 18 and insulation films 16, 17 may be formed.

In the processes of forming core layer 81, cladding layer 82, embedding region 18, or insulation films 16, 17, heating in each process causes the p-type dopant in third semiconductor layer 131 to diffuse toward fourth semiconductor layer 130. Therefore, in the thickness direction of first semiconductor layer 11, interface M2 between third semiconductor layer 131 that is defined as the p-type layer and fourth semiconductor layer 130 that is defined as the n-type or i-type (undoped) layer moves closer to first semiconductor layer 11. As a result, the distance between center position M1 of core layer 81 and interface M2 becomes smaller in the thickness direction of first semiconductor layer 11. An amount that interface M2 moves by heating is, for example, 20 nm to 200 nm. The amount that interface M2 moves due to heating can be estimated in advance, and the position of interface M2 when forming light-absorbing layer 13 can be determined based on the estimated amount. For example, if the amount that interface M2 will move due to heating is estimated to be 50 nm, the position of interface M2 when forming light-absorbing layer 13 is shifted by 50 nm from the position corresponding to center position M1 of core layer 81. This makes it possible to manufacture light-receiving device 2 with a small distance between center position M1 of core layer 81 and interface M2 in the thickness direction of first semiconductor layer 11.

A structure and a characteristic of a light-receiving device according to a first example will be described. The light-receiving device of the first example is an example of the light-receiving device of the modification shown in FIG. 5. The light-receiving device of the first example has the following structure.
Substrate 10: Semi-insulating InP substrate
First semiconductor layer 11: n-type InP layer (n-type dopant: Si)
Buffer layer 111: n-type InP layer (n-type dopant: Si)
Core layer 81: i-type GaInAsP layer
Cladding layer 82: i-type InP layer
Semiconductor layer 12: i-type GaInAsP layer
Fourth semiconductor layer 130: i-type GalnAs layer
Third semiconductor layer 131: p-type GalnAs layer (p-type dopant: Zn)
Second semiconductor layer 14: p-type InP layer (p-type dopant: Zn)
Contact layer 15: p-type GalnAs layer (p-type dopant: Zn)

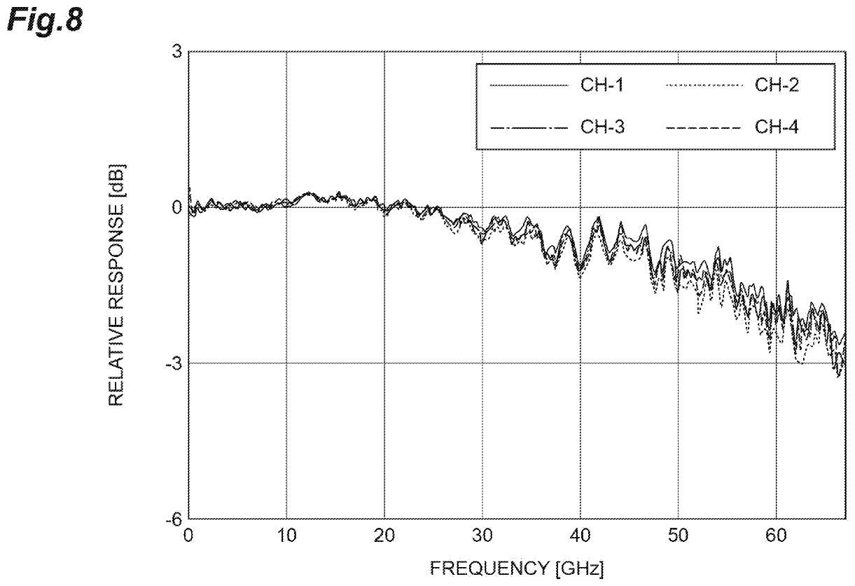

A frequency response characteristic for each of light-receiving element portions 6a to 6d according to the first example was measured. A reverse bias voltage applied to each of light-receiving element portions 6a to 6d is 2.5 V. A power of optical signal La input to input port 4a is equal to a power at which the light current is 3 mA. The results are shown in FIG. 8.

FIG. 8 shows an example of a graph of the frequency response characteristic of the light-receiving device. The horizontal axis of the graph represents the frequency (GHz), and the vertical axis represents the relative response (dB). CH-1 shows the frequency response characteristic of light-receiving element portion 6a. CH-2 shows the frequency response characteristic of light-receiving element portion 6b. CH-3 shows the frequency response characteristic of light-receiving element portion 6c. CH-4 shows the frequency response characteristic of light-receiving element portion 6d. As shown in FIG. 8, the 3-dB bandwidth of each of light-receiving element portions 6a to 6d was about 65 GHz or higher, and had a broad bandwidth.

In addition, the average light sensitivity of light-receiving elements 6a to 6d was calculated. The average light sensitivity was 0.154 A/W, which is high sensitivity. The average light sensitivity Rₑₛₚ (A/W) is calculated by the following equation (1). lₐᵥₑ (A) represents the average value of the currents output from light-receiving element portions 6a to 6d. Pin (W) represents the power of optical signal La input to input port 4a.

Rₑₛₚ=T_{aw}/Pᵢₙ (1)

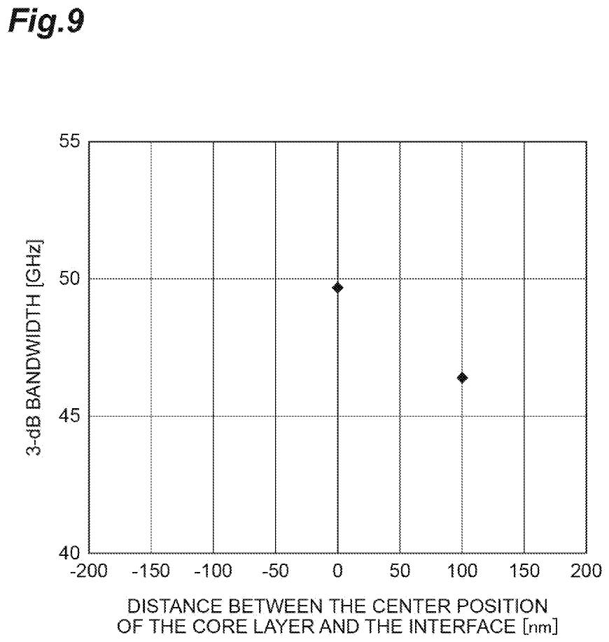

By the method shown in FIGS. 7A to 7C, light-receiving devices for second and third examples were manufactured. Each of the light-receiving devices has a similar structure to the light-receiving device for the first example. The light-receiving devices according to the second example and the third examples have light-absorbing layers 13 having the same thickness. In the second example, before forming optical waveguide structure 80, the thickness of fourth semiconductor layer 130 was 50 nm larger than the thickness of third semiconductor layer 131. Therefore, in the thickness direction of first semiconductor layer 11, the distance between the position corresponding to center position M1 of core layer 81 and interface M2 (see FIG. 7B) was 50 nm. In the third example, the thickness of fourth semiconductor layer 130 was 150 nm larger than the thickness of third semiconductor layer 131 before optical waveguide structure 80 was formed. Therefore, in the thickness direction of first semiconductor layer 11, the distance between the position corresponding to center position M1 of core layer 81 and interface M2 was 150 nm. The amount of moving of interface M2 by Zn diffusion estimated in advance is 50 nm. Therefore, in the second example, the light-receiving device with a distance of 0 nm between center position M1 and interface M2 of core layer 81 should be obtained. In the third example, the light-receiving device with a distance of 100 nm between center position M1 and interface M2 of core layer 81 should be obtained. For the light-receiving devices according to the second and third examples, the frequency response characteristics were measured and the 3-dB bandwidths were calculated as in the first example. The results are shown in FIG. 9.

FIG. 9 shows an example of a graph of the relationship between the distance between the center position of the core layer and the interface and the 3-dB bandwidth. The horizontal axis of the graph represents the distance between center position M1 of core layer 81 and interface M2. When interface M2 shifts from center position M1 of core layer 81 away from first semiconductor layer 11, the distance is defined as positive. When interface M2 shifts from center position M1 of core layer 81 to be closer to first semiconductor layer 11, the distance is defined as negative. The vertical axis represents 3-dB bandwidth. As shown in FIG. 9, the light-receiving device of the second example had a larger 3-dB bandwidth than that of the light-receiving device of the third example. Therefore, the smaller the difference between center position M1 and interface M2 of core layer 81 is, the broader the bandwidth of the light-receiving device can be.

Although suitable embodiments of the present disclosure have been described in detail above, the present disclosure is not limited to the above embodiments.

For example, when first semiconductor layer 11 is a p-type layer and second semiconductor layer 14 is an n-type layer, third semiconductor layer 131 having the p-type is placed between first semiconductor layer 11 and fourth semiconductor layer 130. In this case, semiconductor layer 12 is placed between fourth semiconductor layer 130 and second semiconductor layer 14.

The composition of core layer 81 is not limited to the InGaAsP, but can be, for example, the AlGaInAs .

The above embodiment illustrates a configuration in which optical waveguide portions 8a to 8f and light-receiving element portions 6a to 6d are integrated on a common substrate 10. However, other InP-based electronic devices (e.g., heterojunction bipolar transistors), light-electric conversion circuits including capacitors and resistors may be further integrated on substrate 10.

In the above embodiment, first semiconductor layer 11 having the first conductivity type is provided on substrate 10, but when substrate 10 is a semiconductor substrate having the first conductivity type, first semiconductor layer 11 may be omitted. In that case, the semiconductor substrate having the first conductivity type becomes the first semiconductor layer having the first conductivity type. All the relationships between first semiconductor layer 11 and other components in the above explanation can be read as relationships between the semiconductor substrate having the first conductivity type and other components.

The embodiments disclosed herein should be considered illustrative in all respects and not restrictive. The scope of the invention is indicated by the claims, not in the sense described above, and it is intended to include all modifications within the meaning and scope of the claims.

What is claimed is:

1. A light-receiving device comprising:
a first semiconductor layer having a first conductivity type;
an optical waveguide structure disposed on or above a first region of the first semiconductor layer; and
a photodiode structure disposed on or above a second region of the first semiconductor layer adjacent to the first region,
wherein the optical waveguide structure includes
a core layer disposed on or above the first semiconductor layer, and
a cladding layer disposed on the core layer, wherein the photodiode structure includes
a light-absorbing layer disposed on or above the first semiconductor layer, the light-absorbing layer being optically coupled with the core layer, and
a second semiconductor layer having a second conductivity type, the second semiconductor layer being disposed on or above the light-absorbing layer,
wherein the light-absorbing layer includes
a third semiconductor layer having a p-type, and
a fourth semiconductor layer having a n-type or an i-type, the fourth semiconductor layer having a dopant concentration lower than a dopant concentration of an n-type layer that is one of the first semiconductor layer and the second semiconductor layer, and
wherein the third semiconductor layer is disposed between the fourth semiconductor layer and a p-type layer that is the other of the first semiconductor layer and the second semiconductor layer.

2. The light-receiving device according to claim 1, wherein an interface between the third semiconductor layer and the fourth semiconductor layer is a homojunction surface.

3. The light-receiving device according to claim 1, wherein, in a thickness direction of the first semiconductor layer, a distance between a center position of the core layer and an interface between the third semiconductor layer and the fourth semiconductor layer is less than or equal to 100 nm.

4. The light-receiving device according to claim 1, wherein a p-type dopant concentration at an interface between the third semiconductor layer and the fourth semiconductor layer is greater than or equal to 5×10¹⁵ cm⁻³ and less than or equal to 5×10¹⁷ cm⁻³.

5. The light-receiving device according to claim 1, wherein the first semiconductor layer is the n-type layer, wherein the second semiconductor layer is the p-type layer.

6. The light-receiving device according to claim 1, wherein the third semiconductor layer has a bandgap smaller than a bandgap of the second semiconductor layer.

7. The light-receiving device according to claim 1, wherein the third semiconductor layer is a GalnAs layer.

8. The light-receiving device according to claim 1, wherein the third semiconductor layer has a p-type dopant concentration lower than a dopant concentration of the second semiconductor layer.

9. The light-receiving device according to claim 1, wherein the third semiconductor layer has a p-type dopant concentration monotonically decreasing toward fourth semiconductor layer.

10. The light-receiving device according to claim 1, wherein the third semiconductor layer has a p-type dopant concentration greater than or equal to 5×10¹⁶ cm⁻³ and less than or equal to 1×10¹⁸ cm⁻³.

11. The light-receiving device according to claim 1, wherein a thickness of the third semiconductor layer is from 0.1 μm to 0.4 μm.

12. The light-receiving device according to claim 1, wherein the fourth semiconductor layer has a n-type dopant concentration greater than or equal to 5×10¹⁵ cm⁻³ and less than or equal to 1×10¹⁷ cm⁻³.

13. The light-receiving device according to claim 1, wherein the fourth semiconductor layer is undoped.

14. The light-receiving device according to claim 1, wherein a thickness of the fourth semiconductor layer is greater than or equal to a thickness of the third semiconductor layer.

15. The light-receiving device according to claim 1, wherein a thickness of the fourth semiconductor layer is from 0.1 μm to 0.4 μm.

16. The light-receiving device according to claim 1, wherein a p-type dopant concentration of the second semiconductor layer is 5×10¹⁷ cm⁻³ or greater.

17. The light-receiving device according to claim 1, wherein a thickness of the second semiconductor layer is from 0.5 μm to 3 μm.

18. The light-receiving device according to claim 1, wherein the photodiode structure further includes a fifth semiconductor layer between the first semiconductor layer and the light-absorbing layer, wherein the fifth semiconductor layer has a bandgap larger than a bandgap of the fourth semiconductor layer and smaller than a bandgap of the first semiconductor layer.

19. A method of manufacturing a light-receiving device, comprising:
forming a first semiconductor layer having a first conductivity type on a substrate;
forming a light-absorbing layer on or above the first semiconductor layer;
forming a second semiconductor layer having a second conductivity type on or above the light-absorbing layer;
etching away the light-absorbing layer and the second semiconductor layer on or above a first region of the first semiconductor layer to form a photodiode structure including the light-absorbing layer and the second semiconductor layer on or above a second region of the first semiconductor layer adjacent to the first region; and
forming an optical waveguide structure on or above the first region of the first semiconductor layer, the optical waveguide structure including a core layer optically coupled with the light-absorbing layer and a cladding layer disposed on the core layer,
wherein the light-absorbing layer includes
a third semiconductor layer having a p-type, and
a fourth semiconductor layer having a n-type or an i-type, the fourth semiconductor layer having a dopant concentration lower than a dopant concentration of an n-type layer that is one of the first semiconductor layer and the second semiconductor layer, and
wherein the third semiconductor layer is disposed between the fourth semiconductor layer and a p-type layer that is the other of the first semiconductor layer and the second semiconductor layer.

20. The method of manufacturing a light-receiving device according to claim 19, wherein, before forming the optical waveguide structure, in a thickness direction of the first semiconductor layer, an interface between the third semiconductor layer and the fourth semiconductor layer is farther than a position corresponding to a center position of the core layer from the n-type layer that is one of the first semiconductor layer and the second semiconductor layer.
